(19) United States
(12) Patent Application Publication
(10) Pub. No.: US 2011/0060952 A1
(43) Pub. Date: Mar. 10, 2011

(54) Semiconductor integrated circuit

(75) Inventors: Masaki Asai, Kanagawa (JP); Yukitsugu Takasuka, Kanagawa (JP)

(73) Assignee: Renesas Electronics Corporation, Kanagawa (JP)

(21) Appl. No.: 12/805,754

(22) Filed: Aug. 18, 2010

(30) Foreign Application Priority Data
Sep. 7, 2009 (JP) 2009-206124

(51) Int. Cl. G11C 29/04; G06F 11/22

(52) U.S. Cl. 714/718; 714/E11.145

(57) ABSTRACT

The semiconductor integrated circuit including a memory macro includes a memory cell unit, input data holding units, and output data holding units. The input data holding units hold one of values of input data signals and a scan value depending on a scan control signal in accordance with an operating clock. The output data holding units hold one of values held by the input data holding units and data values stored by the memory cell unit depending on a test control signal in accordance with a phase different from a phase to operate the input data holding units. Further, the input data holding units and the output data holding units are alternately connected in series, and one input data holding unit is arranged at the top. A value held by one output data holding unit is transmitted to another input data holding unit arranged at a subsequent stage of the one output data holding units as the scan value.

### INCORPORATION BY REFERENCE

This application is based upon and claims the benefit of priority from Japanese patent application No. 2009-206124, filed on Sep. 7, 2009, the disclosure of which is incorporated herein in its entirety by reference.

### BACKGROUND

1. Field of the Invention

This invention relates to a semiconductor integrated circuit having a memory macro, and particularly relates to a delay fault detection of a semiconductor integrated circuit having a memory macro.

2. Description of Related Art

A stuck-at fault testing (scan) and a delay fault testing (delay scan) have been performed as a quality testing in a semiconductor integrated circuit. A disconnecting or a short circuit in the semiconductor integrated circuit is detected in the stuck-at fault testing. Japanese Unexamined Patent Application Publication No. 4-48493 discloses an example of a semiconductor integrated circuit that executes the stuck-at fault testing.

The delay fault in the semiconductor integrated circuit is detected in the delay fault testing. When the semiconductor integrated circuit which has the delay fault is incorporated to an actual product, an operation error is occurred. In recent years, process segmentation and faster operation of the semiconductor integrated circuit have been carried out. For this reason, the rate of occurring the delay fault in the semiconductor integrated circuit has been rapidly increasing. Thereby, to detect the delay fault is strongly required.

Specifically, in a semiconductor integrated circuit which has a RAM (Random Access Memory) macro, the number of RAM macros that are mounted on the circuit has been increasing. For these reasons, there is a growing need to efficiently and certainly eliminate the delay fault in the circuit around the RAM.

Japanese Unexamined Patent Application Publication No. 2006-4509 (hereinafter, referred to as “Yoshimura et al.”) discloses a semiconductor integrated circuit which detects the delay fault of paths of input from a memory and output to the memory in a memory-embedded LSI (Large Scale Integration).

FIG. 7 is a block diagram showing a configuration of a semiconductor integrated circuit disclosed in Yoshimura et al. A circuit of FIG. 7 includes of scan FFs 901a to 901m, selectors 902a to 902e, delay adjustment circuits 903a to 903e, combination circuits 910a to 910c, a memory 911, and a BIST (Built-in Self Test) 912. Inputs of the combination circuit 910a are connected to the scan FFs 901a to 901d. Outputs of the combination circuit 910a are connected to the corresponding one of inputs of the selectors 902a to 902d. Data output from the BIST 912 is connected to the other inputs of the selectors 902a to 902d. Outputs of selectors 902a to 902d are connected to the memory 911 and the delay adjustment circuits 903a to 903d. The delay adjustment circuits 903a to 903d are connected to inputs of the scan FFs 901e to 901h. An output of the combination circuit 910b is connected to the scan FF 901k. An output of the scan FF 901k is connected to the delay adjustment circuit 903e. An output of the delay adjustment circuit 903e is connected to one input of the selector 902e. A data output of the memory 911 is connected to the other input of the selector 902e. An output of the selector 902e is connected to the combination circuit 910c. An output of the combination circuit 910c is connected to the scan FF 901m. The output of the selector 902e is also connected to the BIST 912.

The scan FFs 901a to 901m configure a scan path. The scan path is configured to receive a value from a normal input terminal D for a scan path test, to receive data from a testing input terminal SI for a scan shift test, and to output data from a testing output terminal SOUT. The selectors 902a to 902d select an output data of the BIST 912 as testing input when a control signal of memory testing is “H”. On the other hand, the selectors 902a to 902d select the other input as a normal operation when the control signal of memory testing is “L”. The selector 902e selects the output of the scan FF 901k when a control signal of test mode is “H” and selects an output data of memory when the control signal of test mode is “L”.

When a path delay testing is carried out on a path from the scan FF 901a via the combination circuit 910a to an ADR terminal of the memory 911, first, the control signal of memory testing is set to “L”, the scan FFs 901a to 901d and the input of the combination circuit 910a are set to an initial value by the scan shift operation to initialize the path to be tested. Next, the scan FFs 901a to 901d and the input of the combination circuit 910a are set to a final value to activate the path to be tested.

The scan FF 901e obtains a value after activating the path in accordance with a timing same as a clock cycle of the memory. The value of the scan FF 901e is shifted to the output terminal by the scan shift operation to perform the test by comparing the value to an expectation value.

When the path delay testing is carried out on a path from a DOUT of the memory 911 via the combination circuit 910c to the scan FF 901m, first, the control signal of test mode is set to “H”, the scan FF 901k and an input of the combination circuit 910c are set to an initial value by the scan shift operation to initialize the path to be tested. Next, the scan FF 901k and an input of the combination circuit 910c are set to a final value to activate the path to be tested.

The scan FF 901m obtains a value after activating the path in accordance with a timing same as a clock cycle of an actual operation. The value of the scan FF 901m is shifted to the output terminal by the scan shift operation to perform the test by comparing the value to an expectation value.

As described above, in the semiconductor integrated circuit of Yoshimura et al., when the path delay testing is carried out on a path from the scan FF 901a via the combination circuit 910a to the ADR terminal of the memory 911, the scan FF 901e obtains the value transmitted from the combination circuit 910a. Therefore, in a signal line from the selector 902a to the ADR terminal, the delay fault is not detected on a path from a point to branch into the scan FF 901e to the ADR terminal. As is similar to the ADR terminal, in signal lines from the selector 902a to terminals of DIN, WE, and CS, the delay fault is not detected on paths from points to branch into the scan FFs 901f to 901h to respective terminals of DIN, WE, and CS. Further, when the path delay testing is carried out on a path from the DOUT of the memory 911 via the combination circuit 910c to the scan FF 901m, the delay fault on the path from the DOUT to the selector 902e cannot be detected.

In the delay fault testing, it is necessary to confirm that an input data is input to the memory macro and an output data is output from the memory macro. However, in the semiconductor integrated circuit of Yoshimura et al., the delay fault on a part of paths can not be detected.

### SUMMARY

The present inventors found that the delay fault is not certainly detected in the semiconductor integrated circuit having the memory macro. Thus, it is difficult to improve the quality.

An exemplary aspect of the present invention is a semiconductor integrated circuit including a memory macro including: a memory cell unit, input data holding units, and output data holding units. The input data holding units hold one of values of input data signals and a scan value depending on a scan control signal in accordance with an operating clock. The output data holding units hold one of values held by the input data holding units and data values stored by the memory cell unit depending on a test control signal in accordance with a phase different from a phase to operate the input data holding units. Further, the input data holding units and the output data holding units are alternately connected in series, and one of the input data holding units is arranged at the top. A value held by one of the output data holding units is transmitted to another one of the input data holding units arranged at a subsequent stage of the one of the output data holding units as the scan value. The input data holding units and the output data holding units are alternately connected in series, so that a scan chain is formed. The scan chain enables to set a value held in the memory macro from outside and output the value held in the memory macro to the outside. This makes it possible to detect the delay fault occurred at a former stage and a subsequent stage of the memory macro by using values held by a part which is previous of (input data holding unit) and a part which is subsequent to (output data holding unit) the memory cell unit. Therefore, it is possible to improve accuracy of the delay fault detection. This leads to improve the quality of the semiconductor integrated circuit.

According to an exemplary aspect of the present invention, it is possible to detect the delay fault in the semiconductor integrated circuit having the memory macro with certainty to improve the quality thereof.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram showing an exemplary configuration of a memory macro included in a semiconductor integrated circuit of a first exemplary embodiment of this invention;

FIG. 2 is a pattern diagram showing an exemplary configuration of a semiconductor integrated circuit having a function to test a delay fault using an SRAM shown in FIG. 1;

FIG. 3 is a flow diagram showing an exemplary operation to test the delay fault in logic cone arranged at a subsequent stage of the SRAM of the first exemplary embodiment;

FIG. 4 is a block diagram showing an exemplary configuration of a memory macro included in a semiconductor integrated circuit of a second exemplary embodiment of this invention;

FIG. 5 is a pattern diagram showing a semiconductor integrated circuit which includes an SRAM having a timing generation circuit;

FIG. 6 is a timing diagram showing an exemplary clock used in the SRAM shown in FIG. 5; and

FIG. 7 is a block diagram showing a configuration of a semiconductor integrated circuit disclosed in Yoshimura et al.

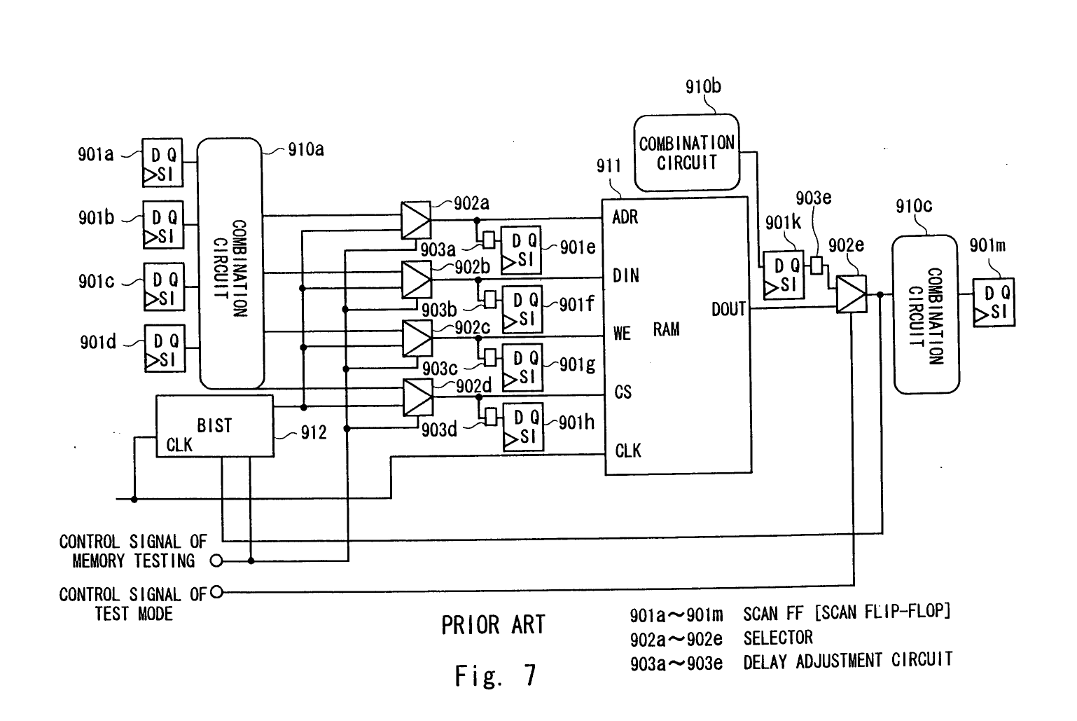

### DETAILED DESCRIPTION OF THE EXEMPLARY EMBODIMENTS

Hereinafter, embodiments of the present invention will be described with reference to the drawings. For clarification of explanation, the following description and drawings are appropriately omitted and simplified. In each drawing, components having the same configuration or function, and corresponding parts are denoted by the same reference symbols, and the description thereof is omitted.

The following exemplary embodiments will be explained using an SRAM as a memory example. The SRAM is a RAM having a macro with synchronous clock. However, this invention is not limited to such SRAM. This invention may be applied to a memory macro including latches which are provided at input/output sides of a memory cell unit and hold data. For example, this invention may be applied to a semiconductor integrated circuit having a memory macro which includes an input latch and an output latch. Further, the input latch is provided at the input side and holds data to be written to the memory cell unit, and the output latch is provided at the output side and holds data to be read from the memory cell unit.

### First Exemplary Embodiment

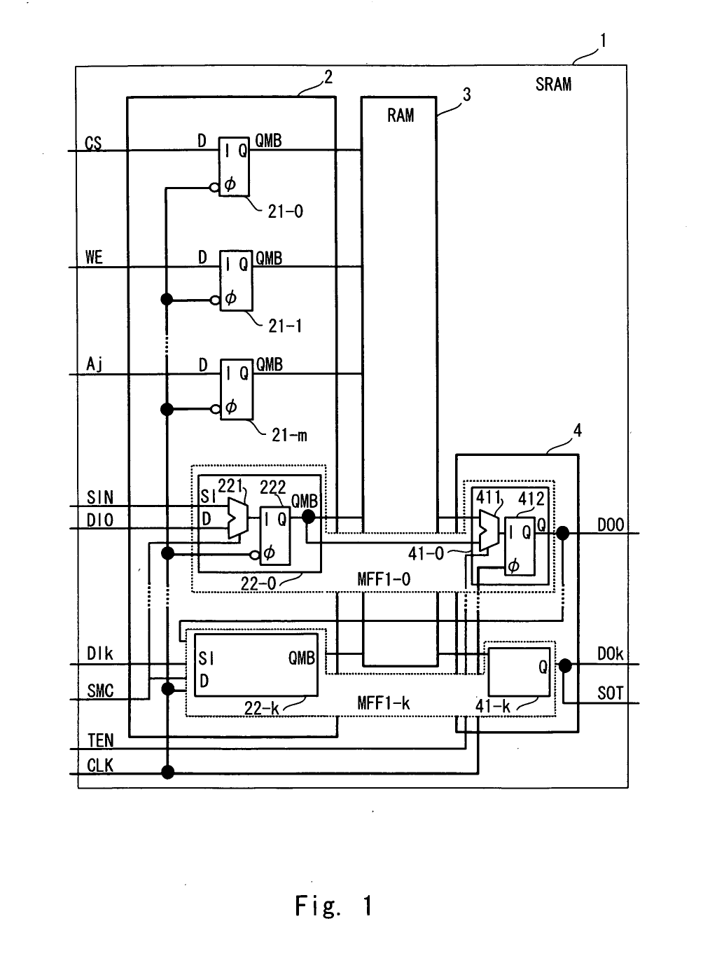

FIG. 1 is a block diagram showing an exemplary configuration of a memory macro included in a semiconductor integrated circuit of a first exemplary embodiment of this invention. This exemplary embodiment shows an SRAM 1 which is the RAM macro with synchronous clock as the memory macro, for example. The SRAM 1 includes an input unit 2, a memory cell unit (RAM) 3, and an output unit 4.

The input unit 2 holds values of memory control signals and input data signals. The input unit 2 writes data to the memory cell unit 3 using the holding values. The input unit 2 may hold a scan value instead of the values of the input data signals. The scan value is a testing data which is set in a state of a scan shift operation.

The memory cell unit 3 is a memory area which stores data to be written according to the value held by the input unit 2. The memory cell unit 3 also reads out the stored data according to the value of the memory control signal to output the data to the output unit 4.

The output unit 4 holds output data read from the memory cell unit 3. The output unit 4 may hold the values held by the input unit 2 instead of the output data value.

The input unit 2 includes plural latches (master latches) 21-0 to 21-m (m is an integer and more than zero) and plural input data holding units 22-0 to 22-k (k is an integer and equal to or more than zero).

The latches 21-0 to 21-m hold the values of the memory control signals (control values). FIG. 1 shows signals “CS”, “WE”, and “Aj” as examples of the memory control signals. Input terminals of the memory control signals are referred to as “input terminal CS”, “input terminal WE”, and “input terminal Aj”. The signal “Aj” is an address signal.

Although plural address signals A0 to Aj (j is an integer and more than zero) are actually input, only the signal “Aj” is shown for clarification of explanation in this example. FIG. 1 also shows examples of the number of the memory control signals and some kinds thereof; however, the memory control signals are not limited to them. The latches 21-0 to 21-m are shown as an example of circuits to hold the values of the memory control signals in FIG. 1, but other circuits may be used.

The input data holding units 22-0 to 22-k hold one of the values of the input data signals and the scan value depending on a scan control signal (hereinafter also referred to as “SMC”) in accordance with a reverse phase of an operating clock. The input data holding units 22-0 to 22-k are provided corresponding to input data signals (DI0 to DOk).

The input data holding units 22-0 to 22-k hold the scan value when the scan control signal is set to a scan shift operation (SMC=“1”, for example). The input data holding units 22-0 to 22-k hold the values of the input data signals when the scan control signal is set to operations other than the scan shift operation (SMC=“0”, for example).

Each of the input data holding units 22-0 to 22-k includes an input selector (also referred to as “input data selector”, “selector circuit”, or “SEL1”) 221 and an input latch (also referred to as “input data latch”, or “DIL”) 222. Although FIG. 1 shows a configuration of the input data holding unit 22-0, the input data holding units 22-1 to 22-k also have the same configuration.

The input selector 221 selects one of the value of one of the input data signals and the scan value depending on the scan control signal. The input selector 221 is connected to the input terminal SMC of the SMC and receives the SMC as a select signal.

The input selector 221 of each of the input data holding units 22-0 to 22-k includes two input terminals. One input terminal D of the input selector 221 is connected to the corresponding input terminal (that is, an input terminal DI0, . . . , or an input terminal DIk) of one of the input data signals (that is, DI0 to DOk). Accordingly, one of the input data signals is input from one of the input terminals DI0 to DIk to one input terminal D of the input selector 221 of one of the input data holding units 22-0 to 22-k which corresponds to the one of the input signals.

Further, the other input terminal SI of the input selector 221 of the input data holding unit 22-0 is connected to an input terminal SIN which receives the scan value (SIN). The scan value is input from the input terminal SIN to the input terminal SI of the input selector 221 of the input data holding unit 22-0. The other input terminals SI of input selectors 221 of the input data holding units 22-1 to 22-k are connected to output terminals of the output unit 4 (one of output terminals of plural output data holding units 41-0 to 41-(k−1) discussed later). Therefore, the input selectors 221 of the input data holding units 22-1 to 22-k receive output values from the output unit 4 as the scan value.

Outputs of the input selectors 221 are input to the input latches 222.

The input latch 222 holds values selected by the input selector 221 in accordance with the reverse phase of the operating clock. An output QMB of the input latch 222 is input to the corresponding bit of the memory cell unit 3, and transmitted to the output unit 4.

The output unit 4 includes plural output data holding units 41-0 to 41-k.

The output data holding units 41-0 to 41-k hold one of values held by the input data holding units 22-0 to 22-k (input holding value) and the data values stored by the memory cell unit 3 (output data value) depending on the test control signal (hereinafter, also referred to as “TEN”) in accordance with a normal phase of the operating clock. One of the values held by the input data holding units 22-0 to 22-k is a value held by the input latch 222.

When the test control signal is set to a test mode (for example, TEN=“1”), each of the output data holding units 41-0 to 41-k holds the value held by one of the input data holding units 22-0 to 22-k which is arranged at a former stage in accordance with the normal phase of the operating clock CLK. When the scan control signal is set to a normal mode, each of the output data holding units 41-0 to 41-k holds the data value stored by the memory cell unit 3.

Each of the output data holding units 41-0 to 41-k includes an output selector (also referred to as “output data selector”, or “SEL2”) 411 and an output latch (also referred to as “output data latch”, or “DOL”) 412. Although FIG. 1 shows a configuration of only the output data holding unit 41-0, the output data holding units 41-1 to 41-k also have the same configuration.

The output selector 411 selects one of the value held by one of the input data holding units 22-0 to 22-k and the data value stored by the memory cell unit 3 depending on the TEN. The output selector 411 is connected to an input terminal of the TEN and receives the TEN as the select signal.

The output selector 411 of each of the output data holding units 41-0 to 41-k includes two input terminals. One input terminal of the output selector 411 is connected to the corresponding bit of the memory cell unit 3. The data value from the memory cell unit 3 is input to the output selector 411 of the corresponding one of the output data holding units 41-0 to 41-k. That is to say, data output from the memory cell unit 3 is input to the one input terminal as the output data value.

Further, the other input terminal of the output selector 411 is connected to the input latch 222 of one of the input data holding units 22-0 to 22-k. That is, the output signal QMB of the input latch 222 is input to the other input terminal of the output selector 411 which one of output data holding units 41-0 to 41-k includes.

The output latch 412 holds a value selected by the output selector 411 in accordance with the normal phase of the operating clock. The output latches 412 of the output data holding units 41-0 to 41-k are connected to the corresponding one of output terminals DO0 to DOk. Further, the output latch 412 of each of the output data holding units 41-0 to 41-(k−1) is connected to the other input terminal SI of the input selector 221 of one of the input data holding units 22-1 to 22-k. The output latch 412 of the output data holding unit 41-k is connected to an output terminal SOT of the scan value. Accordingly, an output signal Q from the output latch 412 is output to the corresponding output terminal which is one of output terminals DO0 to DOk, and the input selector 221, or the output terminal SOT for the scan value.

The operating clock (hereinafter, also referred to as “CLK”) is supplied from the input terminal CLK to each component of the input unit 2 and the output unit 4 (that is, latches 21-0 to 21-m, each input latch 222, and each output latch 412).

The plural input data holding units 22-0 to 22-k and the plural output data holding units 41-0 to 41-k are alternately connected in series as a first chain. The input data holding unit 22-0 is arranged at the top of the first chain (first stage). For example, the value held by the output data holding unit 41-0 (output holding value) is input to the input data holding unit 22-1 arranged at the subsequent stage (latter stage) of the output data holding unit 41-0 (the input data holding unit 22-1 being disposed subsequent to the output data holding unit 41-0) as the scan value. A function as D-type•flip-flop with a data selecting function is achieved by a combination of one of the input data holding units 22-0 to 22-k and one of the output data holding units 41-0 to 41-k which is arranged at the subsequent stage of the one of the input data holding units 22-0 to 22-k, when the value of the TEN is “1”. Hereinafter, this combination is referred to as “combination MFF1” or “MFF1”. For example, the combination of the input data holding unit 22-0 and the output data holding unit 41-0 is recognized as one MFF1. In FIG. 1, one MFF1 is surrounded by a dotted line. When the value of the TEN is “1”, the MFF1 forms a scan flip-flop. In FIG. 1, (k+1) combinations MFF1-0 to MFF1-k are formed.

The combinations MFF1-0 to MFF1-k form a scan chain composed of D-type•flip-flops with a data selecting function. Therefore, when the test control signal is the test mode and the scan control signal is the scan shift operation, the combinations MFF1-0 to MFF1-k work as the scan chain.

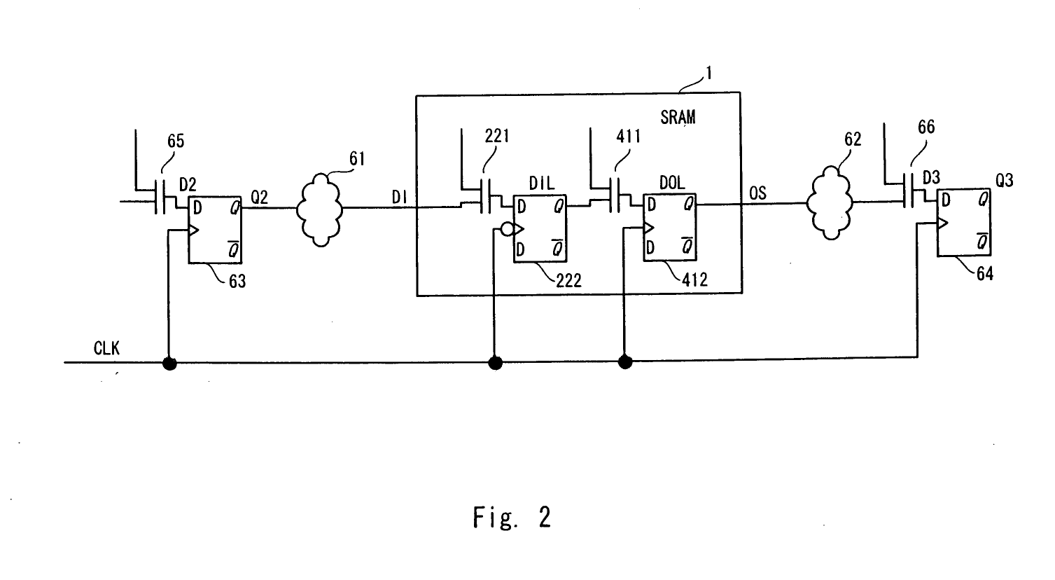

Next, an exemplary configuration to test a delay fault using the SRAM 1 shown in FIG. 1 will be explained referring to FIG. 2. FIG. 2 is a pattern diagram showing an exemplary configuration of a semiconductor integrated circuit having a function to test the delay fault using the SRAM 1 shown in FIG. 1. A semiconductor integrated circuit shown in FIG. 2 includes the SRAM 1, combination circuits 61 and 62, flip-flops (F/F) 63 and 64, and selectors 65 and 66. The selectors 65 and 66 are generally formed of a selection circuit or a selector. Although the SRAM 1 includes the same components as those of FIG. 1, FIG. 2 only shows the input selector 221 and the input latch 222 (DIL) of the input data holding unit 22-0, and the output selector 411 and the output latch 412 (DOL) of the output data holding unit 41-0 as a representative example.

The selector 65 selects a value input to the flip-flop 63. The selector 66 selects a value input to the flip-flop 64. The operating clock CLK is common to the flip-flops 63 and 64, the input latch 222, and the output latch 412.

A delay fault testing is to scan whether the delay fault occurs or not by a unit of one logic cone. The unit of one logic cone to be scanned is a path from an input terminal of a flip-flop arranged at the former stage of a combination circuit to an input terminal of a flip-flop arranged at the subsequent stage of the combination circuit. For example, in the case of testing a logic cone arranged at the former stage of the SRAM 1 in FIG. 2, the delay fault testing is to scan a path from the flip-flop 63 to the input latch 222. Alternatively, in the case of testing a logic cone arranged at the subsequent stage of the SRAM 1, the delay fault testing is to scan a path from the output latch 412 to the flip-flop 64.

When the delay fault testing is performed on a path from the flip-flop 63 via the combination circuit 61 to the terminal DI of the SRAM 1, for example, after the TEN is set to the test mode (TEN=“1”), the SMC is set to the scan shift operation (SMC=“1”), and the input of the flip-flop 63, and the inputs of the combinations MFF1-0 to MFF1-k are set to desired values by the scan shift operation. Next, the SMC is set to a scan capture operation (state of scan capture operation) (SMC=“0”), the path to be tested is activated (Launch, Capture) in accordance with an operating clock for normal operation or a cycle clock equal to or less than the level of the operating clock. After that, the SMC is set to the scan shift operation (SMC=“1”), and the value held by the input latch 222 is retrieved (scan out).

It is possible to detect the delay fault including that occurred in a line to connect to the input latch 222 in the SRAM 1 in the logic cone arranged at the former stage of the SRAM 1. Further, a value held in the input latch 222 can be checked. This makes it possible to detect a delay fault with certainty.

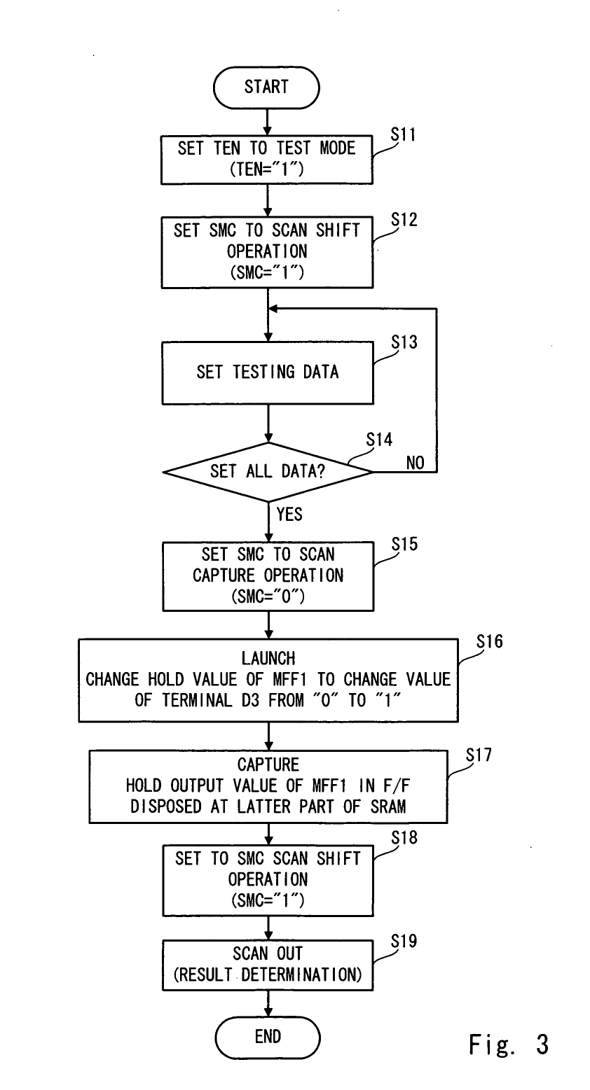

The semiconductor integrated circuit shown in FIG. 2 is capable of performing the delay fault testing of the logic cone arranged at the subsequent stage of the SRAM 1 by using the value from the output latch 412. In other words, it is possible to scan the delay fault including that in a line to connect the output latch 412. The detail of this testing will be explained referring to FIG. 3.

FIG. 3 is a flow diagram showing an exemplary operation to test the delay fault in the logic cone arranged at the subsequent stage of the SRAM of the first exemplary embodiment. An exemplary testing operation will be explained using an example to change an input value of the flip-flop 64 from “0” to “1” between the SRAM 1 and the flip-flop 64. The flip-flop 64 is arranged at the subsequent stage of the SRAM 1 and holds the value from the SRAM 1. Although FIG. 2 merely shows one MFF1 within the SRAM 1, the SRAM 1 includes (k+1) combinations of MFF1-0 to MFF1-k as shown in FIG. 1. Further, it is assumed that (k+1) flip-flops 63 are provided at the former stage of the SRAM 1, (k+1) flip-flops 64 are provided at the subsequent stage of the SRAM 1, (k+1) selectors 65 and (k+1) selectors 66 are provided, and (k+1) flip-flops form the scan chain. Here, it is also assumed that a state of the SRAM 1 is the test mode when the TEN is equal to “1”, and the state is the scan shift operation when the SMC is equal to “1”.

The TEN is set to “1” to set the state of the SRAM 1 to the test mode (S11). The SMC is set to “1” to set the state to the scan shift operation.

Subsequently, testing data is set (S13). Here, the holding value of the combinations MFF1-0 to MFF1-k is set so as to set the terminals D3 to “0” first. Next, the input data signals DI0 to DIk are set so as to change the terminals D3 to “1”. In this case, repeat these data setting from the combination MFF1-0 and the input data signal DI0 to the combination MFF1-k and the input data signal DIk (S14) are repeated in series.

The data setting of the combinations MFF1-0 to MFF1-k are made as follows. Data “0” is input from the input terminal SIN as the scan value. The input selector 221 of the input data holding unit 22-0 selects the scan value depending on the value of the SMC. The input latch 222 of the input data holding unit 22-0 holds “0” as the scan value output from the input selector 221 of the input data holding unit 22-0 in accordance with the reverse phase of the CLK. Subsequently the output selector 411 of the output data holding unit 41-1 selects the output signal value “0” (input holding value) output from the input latch 222 of the input data holding unit 22-0 depending on the TEN. The output latch 412 of the output data holding unit 41-1 holds the value “0” output from the output selector 411 of the output data holding unit 41-1 in accordance with the normal phase of the CLK.

In response to end of testing data setting (YES in S14), the SMC is set to “0” to set the state to the scan capture operation (S15). After that, in response of performing a launch, the flip-flops 64 obtain “0”. At the same time, the combinations MFF1-0 to MFF1-k obtain the values of input data signals DI0 to DIk input from the input terminals DI0 to DIk (S16). This enables to change the values held by the combinations MFF1-0 to MFF1-k (output latches 412) from the value so as to set the input terminals D3 of the flip-flops 64 to “0” to the value so as to set the input terminals D3 to “1”. Next, a capture is performed. This enables the flip-flops 64 to hold “1” (S17). In this case, a term from the launch to the capture is equal to or less than the frequency of the normal operation clock.

After the capture, the SMC is set to “1” to set the state to the scan shift operation (S18). A scan out is performed to determine a testing result (S19). Here, the scan out is performed on the scan chain of flip-flops 64 arranged at the subsequent stage of the SRAM 1 to determine whether the delay fault occurs.

As described above, the use of the SRAM 1 of this exemplary embodiment makes it possible to improve the quality of the delay fault testing for the memory macro and the logic cones arranged at the former and subsequent stages of the memory macro. Specifically, this exemplary embodiment enables the delay fault testing to scan paths within the memory macro, which include a path to reach the input terminals of the input data holding units 22-0 to 22-k and a path from output terminals of the output data holding units 41-0 to 41-k. That is to say, this exemplary embodiment enables the delay fault testing to scan the paths which are the same as paths of the normal operation. This makes it possible to confirm transmissions of data signals input to the memory macro and transmissions of data signals output from the memory macro with certainty. In the Yoshimura et al., the delay fault testing does not scan the paths within the memory macro. Thereby this exemplary embodiment can achieve higher quality than the technique of Yoshimura et al.

Moreover, this exemplary embodiment may be explained as below. This exemplary embodiment uses input latches and output latches in existence. The input latches and the output latches use the same operating clock. The output latches operate with the normal phase of the operating clock and the input latches operate with the reverse phase of the operating clock. This exemplary embodiment may include the following components.
The input selectors (selection circuits SEL1) are connected to inputs of the data input latches (DIL) corresponding to the data input signals of the memory macro and select the inputs of the data input latches depending on the select signal SMC. Each of the input selectors includes two inputs.
The output selectors (selection circuits SEL2) are connected to inputs of the output latches (DOL) corresponding to the data output signals of the memory macro and select the inputs of the output latches depending on the select signals TEN. Each of the output selectors includes two inputs.

Lines connect the two inputs of the input selectors as follows. One input is connected to one of the input terminals DI0 to DIk of the memory macro (one of the input data signals DI0 to DIk) by a first line. The other input is connected to the input terminal SIN of the scan value (SIN) or one of outputs of the output latches by a second line.
Lines connect the two inputs of the output selectors as follows. One input is connected to one of output terminals DO0 to DOk of the memory cell unit by a third line. The other input is connected to one of the outputs of the input latches by a forth line.

The use of the above described configuration enables the input selector 221, the input latch 222, the output selector 411, and the output latch 412 to operate as the D-type•flip-flop with a data selecting function by the select signal TEN.

In this configuration, the use of existing latches enables reduction of the number of additional circuits. In particular, the configuration of FIG. 1 makes it possible to make a configuration for the delay fault testing by adding the input selectors 221, the output selectors 411, and the lines. The number of additional circuits is less than that of Yoshimura et al. This enables the chip dimensions of the semiconductor integrated circuit to be smaller and reduction of costs to manufacture the semiconductor integrated circuit.

Furthermore, the scan chain formed in the memory macro makes setting of testing data easier. Specifically, the scan chain enables the combinations MFF1-0 to MFF1-k to be set by the scan value (SIN) which is input from the input terminal SIN. Further, the scan chain formed in the memory macro makes it easier to retrieve the testing result. This makes it possible to reduce testing time. Especially, there is no need to set the testing data to the combinations MFF1-0 to MFF1-k by using flip-flops arranged at the former stage of the memory macro, because the scan chain makes it possible to set the testing data to the combinations MFF1-0 to MFF1-k. Therefore, this can facilitate generation of the testing data and reduce time required to generate the testing data.

### Second Exemplary Embodiment

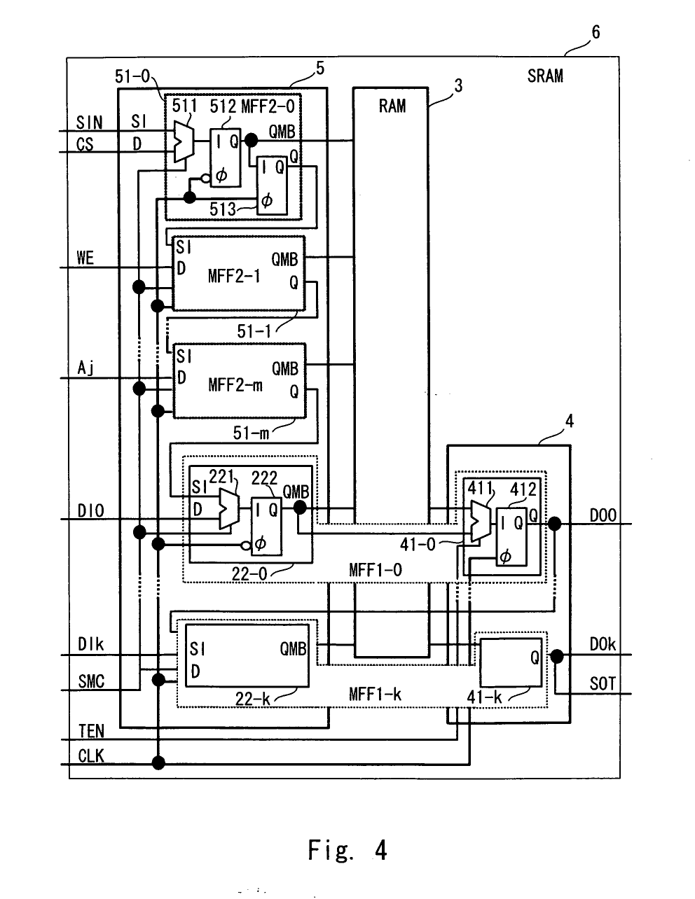

An exemplary embodiment to form the scan chain with respect to the latches 21-0 to 21-2 which receive the memory control signal will be explained in this embodiment. FIG. 4 is a block diagram showing an exemplary configuration of a memory macro included by a semiconductor integrated circuit of the second exemplary embodiment of this invention. An SRAM 6 includes an input unit 5 instead of the input unit 2 shown in FIG. 1. The input unit 5 includes controlling value holding units 51-0 to 51-m configured to have additional circuits in addition to the latches 21-0 to 21-m shown in FIG. 1. A configuration shown in FIG. 4 is the same as FIG. 1 except for the above description and connections of the input data holding unit 22-0.

Each of the controlling value holding units 51-0 to 51-m includes a master selector (SELL) 511, a master latch (ML) 512, and a slave latch (SL) 513. Although FIG. 4 shows the configuration of the controlling value holding unit 51-0, the controlling value holding units 51-1 to 51-m also include the same configuration.

The master selector 511 selects one of the value of the memory control signal and the scan value depending on scan control signal. The master selector 511 is connected to the input terminal SMC of the SMC and receives the SMC as a select signal.

The master selector 511 of each of the controlling value holding unit 51-0 to 51-m includes two input terminals. One input terminal D of the master selector 511 is connected to one of the input terminals of the corresponding memory control signal (input terminal CS, input terminal WE, or input terminal Aj). Each of the memory control signals CS, WE, and Aj is input to the input terminal D of the master selector 511 from one of the input terminals of the corresponding memory control signal, that is, one of input terminals of the input terminal CS, the input terminal WE, and the input terminal Aj.

Further, the other input terminal SI of the master selector 511 of the controlling value holding unit 51-0 is connected to the input terminal SIN which receives the scan value (SIN). The scan value is input from the input terminal SIN to the other input terminal SI of the master selector 511 of the controlling value holding unit 51-0. The other input terminals SI of master selectors 511 of the controlling value holding units 51-1 to 51-m are connected to output terminals of the slave latches 513. Therefore, the master selector 511 of the controlling value holding units 51-1 to 51-m receive output values output from the slave latches 513 as the scan value.

Outputs of the master selectors 511 are input to the master latches 512.

The master latch 512 holds values selected by the master selector 511 in accordance with the reverse phase of the operating clock. The output QMB of the master latch 512 is input to the corresponding terminal of the memory cell unit 3, and transmitted to the slave latch 513.

The slave latch 513 holds the value held by the master latch 511 in accordance with the normal phase of the operating clock. The output Q of the slave latch 513 is connected to the terminal SI of the master selector 511 of the controlling value holding unit arranged at the subsequent stage of the one of the controlling value holding units 51-0 to 51-m.

The above described configuration enables the controlling value holding units 51-0 to 51-m to operate as the D-type•flip-flop with a data selecting function. Hereinafter, “controlling value holding unit” is also referred to as “unit MFF2”, or “MFF2”. FIG. 4 shows (m+1) units MFF2-0 to MFF2-m and (k+1) combinations MFF1-0 to MFF1-k.

Further, the controlling value holding units 51-0 to 51-m are connected each other in series as a second chain. The value held by the slave latch 513 of one of the controlling value holding units 51-0 to 51-(m−1) is input to the master selector 511 of another one of the controlling value holding units 51-1 to 51-m arranged at the subsequent stage of the one of the controlling value holding units 51-0 to 51-(m−1) as the scan value. The value held by the slave latch 513 of the controlling value holding unit 51-m, which is arranged at the end of the second chain, is input to the input data holding unit 22-0, which is arranged at the top of the first chain, as the scan value.

This connection enables the controlling value holding units 51-0 to 51-m, the input data holding units 22-0 to 22-k, and the output data holding units 41-0 to 41-k to form a scan chain composed of the D-type•flip-flop with a data selecting function. Therefore, when the test control signal is in the test mode and the scan control signal is in the scan shift operation, this connection operates as the scan chain (multistep shift register). This makes it possible to detect the delay fault in the memory macro and the logic cones arranged at the former and subsequent stages of the memory macro by the delay scan.

The SRAM 6 of this exemplary embodiment forms a configuration for the delay fault testing similarly to the first exemplary embodiment shown in FIG. 2. In addition to the SRAM 1 of the first exemplary embodiment shown in FIG. 2, the SRAM 6 can confirm the value of the memory control signal output from the logic cone arranged at the former stage of the SRAM 6. This makes it possible to detect the delay fault which occurs in the path from the logic cone to the input terminal of the memory control signal regarding the delay fault testing for the logic cone arranged at the former stage of the SRAM 6.

Further, the SRAM 6 can set the value of the memory control signal to a desired value. For example, the SRAM 6 can receive desired values for the memory control signal and data signal from the input terminal SIN so that each latch hold the desired values to perform the delay fault testing.

According to this exemplary embodiment, in addition to the exemplary advantageous effects of the first exemplary embodiment, it is possible to improve quality of the delay fault testing with respect to the memory control signal of the logic cone arranged at the former stage of the memory macro.

### Other Exemplary Embodiment

Above exemplary embodiments are described using the SRAM as an example of the memory, but the memory is not limited to this. This invention can be applied to memories other than the SRAM, such as a RAM, or a ROM (Read Only Memory) which has a memory macro including latches provided at the input and output sides of a memory cell unit.

Above exemplary embodiments are explained as an example that the input data holding unit and the master latch hold the values in accordance with the reverse phase of the operating clock, the output data holding unit and the slave latch hold the values in accordance with the normal phase of the operating clock. Phases of the operating clock are not limited to them. It is only required that one phase of the operating clock used by the input data holding unit and the master latch and the other phase used by the output data holding unit and the slave latch are reverse each other. Therefore, one may use the normal phase of the operating clock, and the other may use the reverse phase of the operating clock.

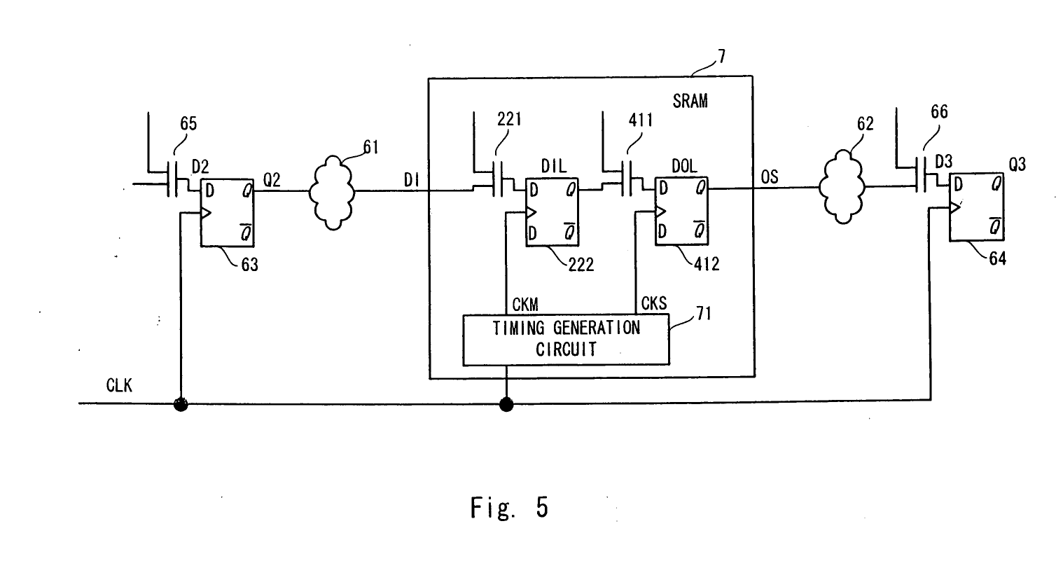

Further, above exemplary embodiments are explained using the normal and reverse phases of the operating clock CLK. Phases are not limited to them, and it is only required that one phase used by the plural output data holding units and the other phase, which is different from the one phase, used by the plural input data holding units may be used. For example, it may be possible to use clocks having different phases each other by shifting the phase of the operating clock. FIG. 5 is a pattern diagram showing a semiconductor integrated circuit which includes an SRAM having a timing generation circuit. An SRAM 7 includes a timing generation circuit 71. The timing generation circuit 71 generates clocks CKS and CKM having different phases each other based on the operation clock CLK.

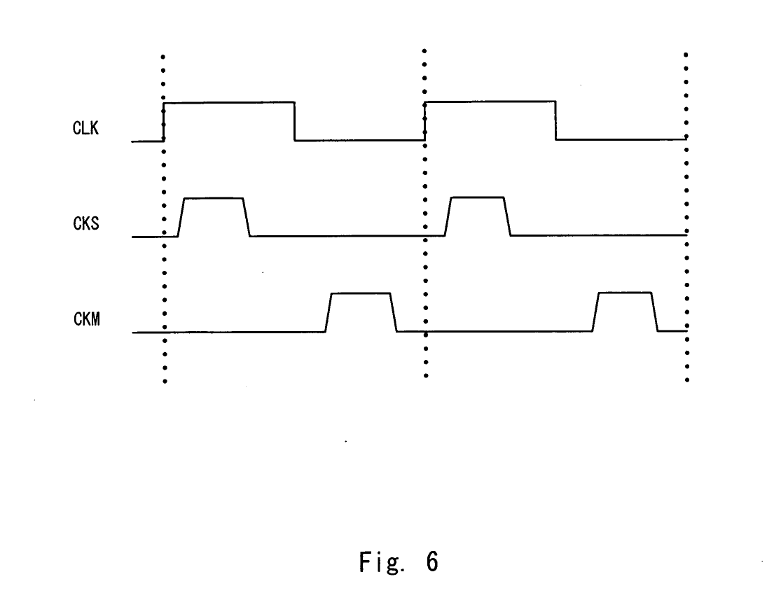

FIG. 6 shows exemplary clocks such as an operating clock CLK and clocks CKS and CKM. The operating clock CLK and clocks CKS and CKM have the same frequency. High level period and low level period may be different each other between the clocks CKS and CKM. Thus, it is only required that one clock used by the input data holding unit (the input latch) and another clock used by the output data holding unit (the output latch) have the same frequency and have a phase difference. Note, one clock used by the master latch and another clock used by the slave latch are similar as above.

FIG. 5 shows the SRAM 7 as an example that the timing generation circuit 71 is incorporated into the SRAM 1 shown in FIG. 1. It may be possible to incorporate the timing generation circuit 71 into the SRAM 6 shown in FIG. 4. In this case, an SRAM may be configured in such a way that the input latch 222 and the master latch 512 use one clock CKM, and the output latch 412 and the slave latch 513 use another clock CKS. That is to say, an SRAM may be configured in such a way that the input data holding units 22-0 to 22-k and the master latches 512 of each of the controlling value holding units 51-0 to 51-m use the one clock CKM, and the output data holding units 41-0 to 41-k and the slave latches 513 of each of the controlling value holding units 51-0 to 51-m use the another clock CKS.

While the invention has been described in terms of several exemplary embodiments, those skilled in the art will recognize that the invention can be practiced with various modifications within the spirit and scope of the appended claims and the invention is not limited to the examples described above.

Each of the exemplary embodiments can be combined as desirable by one of ordinary skill in the art.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor integrated circuit including a memory macro comprising:
a memory cell unit;
a plurality of input data holding units that hold one of values of input data signals and a scan value depending on a scan control signal in accordance with an operating clock; and
a plurality of output data holding units that hold one of values held by the plurality of the input data holding units and data values stored by the memory cell unit depending on a test control signal in accordance with a phase different from a phase to operate the plurality of the input data holding units;
wherein the plurality of the input data holding units and the plurality of the output data holding units are alternately connected in series, one of the plurality of the input data holding units being arranged at the top, and
a value held by one of the plurality of the output data holding units is transmitted to another one of the plurality of the input data holding units arranged at a subsequent stage of the one of the plurality of the output data holding units as the scan value.

2. The semiconductor integrated circuit according to claim 1, wherein the plurality of the input data holding units hold the scan value when the scan control signal is set to a scan shift operation, and hold the values of the input data signals when the scan control signal is set to operations other than the scan shift operation.

3. The semiconductor integrated circuit according to claim 1, wherein the plurality of the output data holding units hold the values held by the plurality of the input data holding units when the test control signal is set to a test mode, and hold the data values stored by the memory cell unit when the test control signal is set to a normal mode.

4. The semiconductor integrated circuit according to claim 2, wherein the plurality of the output data holding units hold the values held by the plurality of the input data holding units when the test control signal is set to a test mode, and hold the data values stored by the memory cell unit when the test control signal is set to a normal mode.

5. The semiconductor integrated circuit according to claim 1, wherein
each of the plurality of the input data holding units includes
an input selector that selects one of a value of one of the input data signals and the scan value depending on the scan control signal; and
an input latch that holds the value selected by the input selector in accordance with the operating clock;
each of the plurality of the output data holding units includes
an output selector that selects one of the value held by the input latch and the data value depending on the test control signal; and
an output latch that holds the value selected by the output selector in accordance with a phase different from a phase to operate the input latch.

6. The semiconductor integrated circuit according to claim 2, wherein
each of the plurality of the input data holding units includes
an input selector that selects one of a value of one of the input data signals and the scan value depending on the scan control signal; and
an input latch that holds the value selected by the input selector in accordance with the operating clock;
each of the plurality of the output data holding units includes
an output selector that selects one of the value held by the input latch and the data value depending on the test control signal; and
an output latch that holds the value selected by the output selector in accordance with a phase different from a phase to operate the input latch.

7. The semiconductor integrated circuit according to claim 3, wherein
each of the plurality of the input data holding units includes
an input selector that selects one of a value of one of the input data signals and the scan value depending on the scan control signal; and
an input latch that holds the value selected by the input selector in accordance with the operating clock;
each of the plurality of the output data holding units includes
an output selector that selects one of the value held by the input latch and the data value depending on the test control signal; and
an output latch that holds the value selected by the output selector in accordance with a phase different from a phase to operate the input latch.

8. The semiconductor integrated circuit according to claim 4, wherein
each of the plurality of the input data holding units includes
an input selector that selects one of a value of one of the input data signals and the scan value depending on the scan control signal; and
an input latch that holds the value selected by the input selector in accordance with the operating clock;
each of the plurality of the output data holding units includes
an output selector that selects one of the value held by the input latch and the data value depending on the test control signal; and
an output latch that holds the value selected by the output selector in accordance with a phase different from a phase to operate the input latch.

9. The semiconductor integrated circuit according to claim 5, wherein
the value held by the input latch included in one of the plurality of the input data holding units is transmitted to the output selector included in one of the plurality of the output data holding units arranged at a subsequent stage of the one of the plurality of the input data holding units, and
the value held by the output latch included in one of the plurality of the output data holding units is transmitted to the input selector included in one of the plurality of the input data holding units arranged at a subsequent stage of the one of the plurality of the output data holding units.

10. The semiconductor integrated circuit according to claim 5, wherein
the input latch outputs a value held by itself to the memory cell unit, and
the output selector receives a data value from the memory cell unit.

11. The semiconductor integrated circuit according to claim 1, wherein
the plurality of the input data holding units use one of a normal phase and a reverse phase of the operating clock, and
the plurality of the output data holding units use the other of the normal phase and the reverse phase of the operating clock.

12. The semiconductor integrated circuit according to claim 1, wherein
the plurality of the output data holding units use a clock having the same frequency and a phase difference with the clock used by the plurality of the input data holding units.

13. The semiconductor integrated circuit according to claim 1, wherein
the one of the plurality of the input data holding units arranged at the top is connected to an input terminal of the scan value, and
the plurality of the input data holding units and the plurality of the output data holding units form a scan chain composed of a D-type•flip-flop with a data selecting function, when the test control signal is in a test mode and the scan control signal is in a scan shift operation.

14. The semiconductor integrated circuit according to claim 1, further comprising:
a plurality of controlling value holding units that are connected in series; wherein
each of the plurality of controlling value holding units includes
a master selector that selects one of a value of a memory control signal and the scan value depending on the scan control signal;
a master latch that holds the value selected by the master selector in accordance with the operating clock; and
a slave latch that holds the value held by the master latch in accordance with a phase different from a phase to operate the master latch,
the value held by the slave latch of one of the plurality of the controlling value holding units is transmitted to the master selector of another one of the plurality of the controlling value holding units arranged at a subsequent stage of the one of the plurality of the controlling value holding units as the scan value, and
the value held by the slave latch of one of the plurality of the controlling value holding units arranged at the end is transmitted to the one of the plurality of the input data holding units arranged at the top as the scan value.

15. The semiconductor integrated circuit according to claim 12, wherein
one of the controlling value holding units arranged at the top is connected to an input terminal of the scan value, and
the plurality of the controlling value holding unit, the plurality of the input data holding unit, and the plurality of the output data holding unit form a scan chain composed of a D-type•flip-flop with a data selecting function, when the test control signal is in a test mode and the scan control signal is in a scan shift operation.

16. The semiconductor integrated circuit according to claim 14, wherein
the master latch uses a clock same as that of the plurality of the input data holding units, and
the slave latch uses a clock same as that of the plurality of the output data holding units.
